(19) United States
(12) Patent Application Publication
(10) Pub. No.: US 2014/0311636 A1
(43) Pub. Date: Oct. 23, 2014

(54) Radio Frequency Identification Protective Wallet

(71) Applicant: Marie S. Jordan, Scranton, PA (US)

(72) Inventor: Marie S. Jordan, Scranton, PA (US)

(21) Appl. No.: 13/868,292

(22) Filed: Apr. 23, 2013

(51) Int. Cl. H05K 9/00; A45C 1/06

(52) U.S. Cl. CPC H05K 9/0043; A45C 1/06
USPC 150/133

(57) ABSTRACT

A wallet for carrying and shielding portable wireless transponders. A flexible, thin liner capable of blocking electromagnetic radiation is used to construct the wallet. By placing portable wireless transponder into the wallet, the transponder is shielded from being read by an RFID base station and/or reader.

### CROSS-REFERENCE TO RELATED APPLICATIONS

Not Applicable.

### STATEMENT REGARDING FEDERALLY SPONSORED RESEARCH

Not Applicable.

### BACKGROUND

1. Field of Invention

The present invention relates to apparatuses used to shield portable wireless transponders.

2. Description of Related Art

Portable wireless transponders employ RFID, Radio Frequency Identification, as the technology used to collect highway tolls, to serve as personal identification for access control, and to provide means for electronic information interchange, such as credit, etc. Passive RFID tags and wireless cards contain chips (also known as computer chips, microchips, memory chips) which store identification and other information, such as credit card numbers, financial data, etc. Tags may be applied to items to identify the item in much the same way that bar codes are used. Information is retrieved from a transponder by an RFID base station or reader when the transponder is scanned with radio waves by the reader. The transponders may draw their power to function from the interrogation field supplied by the base station which reads or writes information to the transponder.

Examples of passive transponders are described in U.S. Pat. No. 3,713,148 issued to Cardullo and Parks. In its simplest form the RFID tag or device includes a circuit, typically a silicon chip, although more than one chip may be used in the construction of the RFID device. The circuit is generally connected to an antenna. The RFID device or card may take on a variety of forms including that of a tag, a key fob, or a card. A battery may also be employed to extend the range of the device. It is also possible in principle to build devices that function as tags or wireless cards using electrical circuits including only resistors, capacitors and inductors, as is well known by those skilled in the art. In some cases the circuit acts as an antenna and thus a separate antenna is not used.

Other transponders may contain a set of magnetic wires or a set of resonant devices, neither of which contain separate antennae to receive or send a signal upon interrogation but still have memory functions that may be interrogated in a manner similar to tags comprised of an antenna and chip. There are also non-electrical circuit memory devices, which are responsive to interrogation, that may be used to construct identification devices contained within cards and tags. Examples of such memory devices include magnetic devices, or wires such as those described in U.S. Pat. No. 5,538,803, and resonant structures such as are described in U.S. Pat. No. 5,563,583 and U.S. Pat. No. 5,581,257.

A major problem with a RFID transponder is that it could be commanded to send its information without the owner's consent or knowledge. This could release sensitive information (e.g., credit card information) that could potentially harm the owner if it was obtained by someone that was not authorized. The RFID transponder could expose that the owner is in possession of certain items that he/she wishes to remain private.

### SUMMARY

The present invention is designed to prevent unauthorized and unknowing access to RFID transponder information (e.g., to provide protection against identity theft). In addition, the present invention provides protection against magnetic storms which could damage RFID transponders, rendering them useless. The invention comprises a wallet constructed out of a thin sheet of a non-magnetic metallic material that envelopes the RFID transponder that the user wants to protect (e.g., transponding credit card, tablet computer, cellular telephone) when the wallet is in a closed position. This allows a user to place the RFID transponder inside the wallet whenever he/she desires to protect it from unauthorized and unknowing access. When the user wants to use the RFID transponder, he/she simply opens the wallet and removes the transponder. The present invention is therefore an inexpensive and easy to use solution for users who desire to protect their RFID transponders.

### BRIEF DESCRIPTION OF THE DRAWINGS

FIG. 1 is a perspective view of a wallet that is consistent with the present invention.

FIG. 2 is a perspective view of a wallet that is consistent with the present invention.

FIG. 3 is a perspective view of a wallet that is consistent with the present invention.

### DETAILED DESCRIPTION

A wallet consistent with the present invention can be constructed of any known flexible, thin material capable of blocking electromagnetic radiation. Examples include textile fabrics which are coated with a metallic coating (e.g., silver, copper) after weaving or knitting of the fabric, textile fabrics which are primarily formed with natural fibers and include selectively placed conductive yarns, and textile fabrics formed from yarns containing metallic fibers or strands. Such material can be of any size and shaped by any known means such as cutting. The wallet can be designed to fit all manner of known pockets, handbags, and the like used by individuals to store and/or carry wallets.

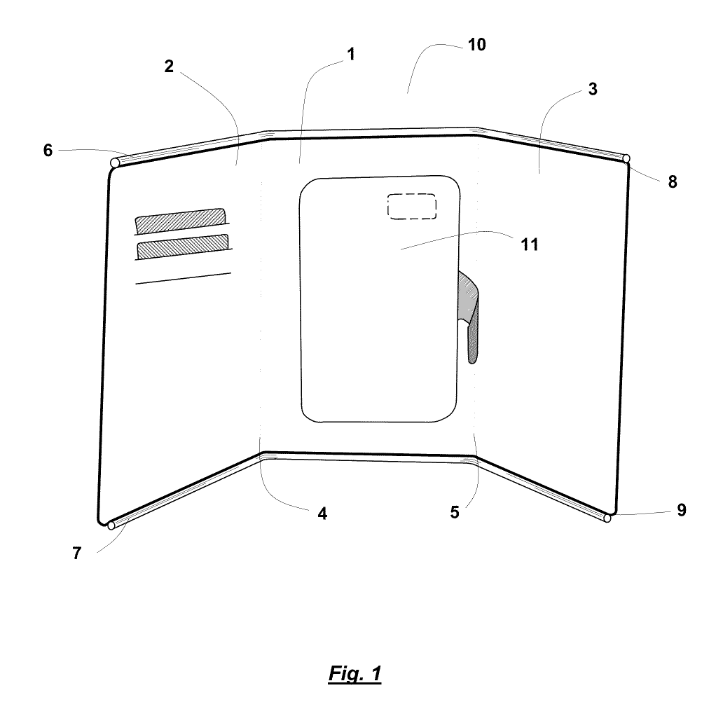

A preferred embodiment of the invention is illustrated in FIG. 1. Referring to FIG. 1, the preferred embodiment is comprised of three panels: a back panel 1 and two side panels (2, 3). A side panel (2, 3) is joined to each vertical edge (4, 5) of the back panel 1 as is shown in FIG. 1, or the three panels are all constructed out of a single piece of fabric. The side panels (2, 3) pivot in both directions about the vertical edges (4, 5) of the back panel 1. A round strip (6, 7) may be joined to the top edge 8 and bottom edge 9 of the wallet 10 as is shown in FIG. 1. A bracket 11 capable of holding transponders such as cellular telephones is preferably joined to the back panel 1.

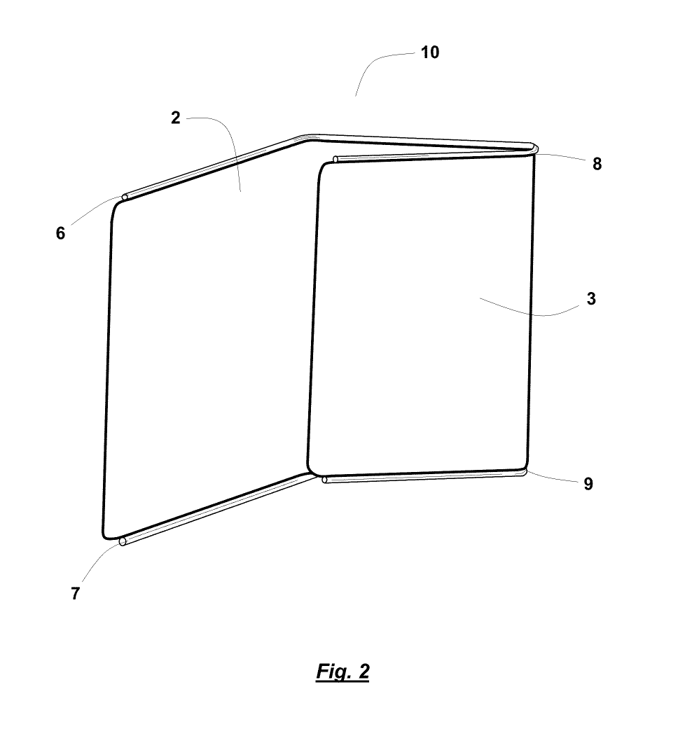

As shown in FIG. 2, the side panels (2, 3) may pivot in an inward direction in front of the bracket (not shown). When fully closed in the inward direction, the side panels (2, 3) cover the transponder held by the bracket and the transponders slipped into the side panels (2, 3), with the round strips (6, 7) covering the top edge 8 and bottom edge 9 of the wallet 10. When closed, the wallet 10 shields the transponders within from RFID base stations and/or readers that come into range of the wallet 10.

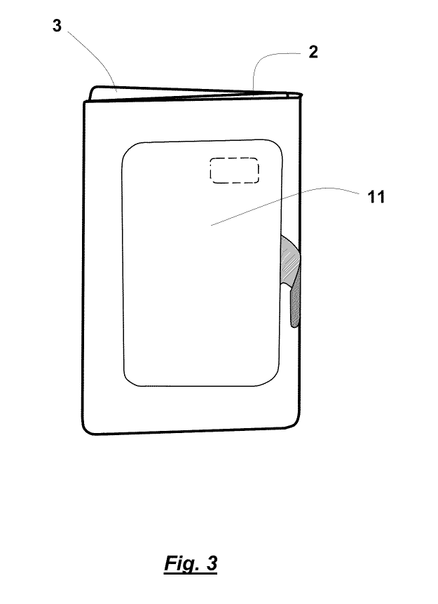

In FIG. 3, the side panels (2, 3) are pivoted in an outward direction. This leaves the bracket 10 exposed, but allows for transponders held by one side panel 2 to be covered by the other side panel 3. This orientation of the invention allows the transponder in the bracket 10 to continue to communicate with RFID base stations and readers, but shields the transponders held within the covered side panel 2.

While the invention has been described in conjunction with specific embodiments thereof it is evident that many alternatives, modifications and variations will be apparent to those skilled in the art. Accordingly, the preferred embodiments of the invention, as set forth herein, are intended to be illustrative, not limiting. Various changes may be made without departing from the true spirit and full scope of the invention, as defined in the following claims.

What is claimed is:

1. A wallet for carrying and shielding portable wireless transponders, comprising:
(a) a back panel constructed of a flexible, thin material capable of blocking electromagnetic radiation; and
(b) at least two side panels constructed of said flexible, thin material.

2. The wallet of claim 1, further comprising round strips joined to the top and bottom edges of said wallet.

3. The wallet of claim 1, wherein said flexible, thin material is constructed of a magnetic material.

4. The wallet of claim 1, wherein said flexible, thin material is constructed of a metallic material.
